(19) United States
(12) Patent Application Publication
(10) Pub. No.: US 2023/0231363 A1
(43) Pub. Date: Jul. 20, 2023

(54) SURFACE-EMITTING SEMICONDUCTOR LASER BASED ON A TRIPLE-LATTICE PHOTONIC CRYSTAL STRUCTURE

(71) Applicant: Changchun Institute of Optics , Fine Mechanics and Physics, Chinese Academy of Sciences, Changchun (CN)

(72) Inventors: Cunzhu TONG, Changchun (CN); Ziye WANG, Changchun (CN); Pinyao WANG, Changchun (CN); Huanyu LU, Changchun (CN); Lijun WANG, Changchun (CN)

(21) Appl. No.: 18/179,048

(22) Filed: Mar. 6, 2023

(30) Foreign Application Priority Data
Jun. 20, 2022 (CN) 202210696112.X

(51) Int. Cl. H01S 5/11; H01S 5/343; H01S 5/18

(52) U.S. Cl. CPC H01S 5/11; H01S 5/34313; H01S 5/18

(57) ABSTRACT

A surface-emitting semiconductor laser based on a triple-lattice photonic crystal structure, including: a P-type electrode, a P-type contact layer, a P-type cladding layer, a photonic crystal layer, an active layer, an N-type cladding layer, an N-type contact layer, an N-type substrate, and an N-type electrode successively arranged from top to bottom. The photonic crystal layer has a triple-lattice photonic crystal structure, which is formed by a plurality of square unit cells arranged periodically. Each square unit cell includes three identical air holes, namely, a first air hole, a second air hole, and a third air hole. A distance between a center of the first air hole and a center of the second air hole is (0.5±0.1) a, and a distance between a center of the third air hole and the center of the second air hole is (0.5±0.1) a, where a is the lattice constant.

### CROSS-REFERENCE TO RELATED APPLICATIONS

This application claims the benefit of priority from Chinese Patent Application No. 202210696112. X, filed on Jun. 20, 2022. The content of the aforementioned application, including any intervening amendments thereto, is incorporated herein by reference in its entirety.

### TECHNICAL FIELD

This application relates to lasers, and more particularly to a surface-emitting semiconductor laser based on a triple-lattice photonic crystal structure.

### BACKGROUND

Photonic crystal surface-emitting laser (PCSEL) is an emerging semiconductor laser which can produce high-power laser emission with ultralow divergence. It has a brilliant application prospect in optical detection and ranging equipment, space communication, sensing and laser processing.

For a band-edge mode PCSEL, the relationship between the optical output power Pₒᵤₜ and the injection current I is shown as follows:

$${P}_{o u t} = \frac{h v}{e} {η}_{i} \frac{{α}_{⊥}}{{α}_{⊥} + {α}_{∥} + {α}_{i}} {η}_{u p} ( I - {I}_{t h} ) ;$$

where v represents mode frequency; e represents unit charge; ηᵢ represents internal quantum efficiency; α_{⊥} represents a total vertical radiation loss; α_{∥} represents an in-plane radiation loss; αᵢ represents an intrinsic loss, which is mainly composed of carrier absorption caused by the waveguide material and scattering loss caused by the rough waveguide wall; ηᵤₚ represents a ratio of the upward radiation loss through the output window to the total vertical radiation loss, and is expressed by α_{⊥up}/α_{⊥}; and Iₜₕ represents a threshold current. When the resonant wavelength λ (μm) is known, the slope efficiency η can be expressed as follows:

$$η = \frac{1.24}{λ} {η}_{i} \frac{{a}_{⊥}}{{a}_{⊥} + {α}_{∥} + {α}_{i}} {η}_{up} .$$

It can be deduced that for a PCSEL with determined wavelength and waveguide material, a higher slope efficiency requires a large vertical radiation constant α_{⊥} and a minimized in-plane losses α_{∥}. However, when the device has a small size (e.g., less than 100 μm) or a low optical confinement factor within the photonic crystal layer (e.g., in the case of surface etched holes), large energy losses, i.e., large in-plane losses, may occur at the edges of the photonic crystal region, which further leads to low slope efficiency and large threshold current density. To address this problem, extensive attempts have been made in the prior art.

Generally, a Fabry-Pérot (FP) cavity is introduced to mitigate the light leakage at the boundary of the photonic crystal region. In 2011, the Institute of Semiconductors of the Chinese Academy of Sciences proposed an electrically pumped lateral cavity photonic crystal surface-emitting laser (LC-PCSEL) based on a commercial epitaxial waveguide without a distributed Bragg reflection (DBR) structure, which is formed by integration of a small-size photonic crystal and the FP cavity. By means of the transverse oscillation and vertical output characteristics of the photonic crystal band-edge mode, the 1.5 μm-band surface-emitting laser is generated at room temperature. This solution was further optimized by the Changchun Institute of Optics, Fine Mechanics and Physics, Chinese Academy of Sciences in 2019 through combining the flat-band effect to enhance the 1.3 μm-band vertical laser output. However, the devices fabricated thereby still have large current beam divergence angles and low slope efficiency.

In December 2019, Renmin Ma's group from the School of Physics of Peking University demonstrated an optically pumped topological bulk surface-emitting laser based on the band-inversion-induced confinement. This new laser has a microscale size, a divergence angle of less than 6°, and a threshold power density of about 4.5 kW/cm⁻². However, the devices made based on this solution have not yet enabled the electrical pumping.

In 2018, Noda's team from Kyoto University (Japan) adopted a double-lattice photonic crystal structure to regulate the vertical and in-plane losses of a large-size (500 μm or more in side length) photonic crystal surface-emitting laser, and a continuous output power of about 7 W and a slope efficiency of 0.48 W/A were reached. In 2021, S. Noda et al. also demonstrated a low-threshold, single-mode electrically pumped photonic crystal surface-emission laser based on a double-lattice photonic crystal structure, whose wavelength was 1.3 μm. In order to optimize the regulation effect, it is often required to form several air holes varying in shape and size within the same cell, which increases the fabrication difficulty. Moreover, there is an upper limit for the enhancement factor of the in-plane feedback of the double-lattice structure.

### SUMMARY

In view of this, an object of the present disclosure is to provide a surface-emitting semiconductor laser, which has improved slope efficiency and reduced threshold current, and is compatible with the far-field beam control of the devices.

Technical solutions of the present disclosure are described as follows.

The present disclosure provides a surface-emitting semiconductor laser based on a triple-lattice photonic crystal structure, comprising:

a P-type electrode;

a P-type contact layer;

a P-type cladding layer;

a photonic crystal layer;

an active layer;

an N-type cladding layer;

an N-type contact layer;

an N-type substrate; and

an N-type electrode;

wherein the P-type electrode, the P-type contact layer, the P-type cladding layer, the photonic crystal layer, the active layer, the N-type cladding layer, the N-type contact layer, the N-type substrate, and the N-type electrode are arranged sequentially from top to bottom; and the photonic crystal layer has a triple-lattice photonic crystal structure; and

the photonic crystal layer is formed by a plurality of square unit cells arranged periodically; each of the plurality of square unit cells has a first air hole, a second air hole, and a third air hole; the first air hole, the second air hole, and the third air hole are the same; and a distance between a center of the first air hole and a center of the second air hole is (0.5±0.1) a, and a distance between a center of the third air hole and the center of the second air hole is (0.5±0.1) a, wherein a is a lattice constant.

Compared to the prior art, the present disclosure has the following beneficial effects.

This application provides a surface-emitting semiconductor laser. The photonic crystal layer in the surface-emitting semiconductor laser is a triple-lattice photonic crystal structure, which enhances the lateral confinement of light and reduces in-plane losses compared with existing photonic crystal structures, thereby reducing the threshold gain and improving the beam far-field profile.

### BRIEF DESCRIPTION OF THE DRAWINGS

To illustrate the technical solutions in the embodiments of the present disclosure or in the prior art more clearly, the accompanying drawings that need to be used in the description of the embodiments or the prior art will be described briefly below. Obviously, presented in the accompanying drawings are only some embodiments of the present disclosure, and other accompanying drawings can be obtained by one of ordinary skill in the art without paying any creative work based on these drawings.

FIG. 1 is a schematic diagram of a surface-emitting semiconductor laser based on a triple-lattice photonic crystal structure according to an embodiment of the present disclosure;

FIG. 2 is a partial cross-sectional view of a photonic crystal layer of the surface-emitting semiconductor laser according to an embodiment of the present disclosure;

FIG. 3 schematically shows a square unit cell of the photonic crystal layer according to an embodiment of the present disclosure;

FIG. 4 is a schematic diagram of a surface-emitting semiconductor laser with coplanar electrodes according to an embodiment of the present disclosure;

FIG. 5 is an energy-band diagram of the photonic crystal layer according to an embodiment of the present disclosure;

FIG. 6 shows deviation range of a center position of air holes of the square unit cell according to an embodiment of the present disclosure; and

FIG. 7 shows a variation of a modulation factor amplitude of the square unit cell with an offset of the air holes according to an embodiment of the present disclosure.

In the drawings, 101, P-type electrode; 102, P-type contact layer; 103, P-type cladding layer; 104, photonic crystal layer; 105, active layer; 106, N-type cladding layer; 107, N-type contact layer; 108, N-type substrate; and 109, N-type electrode.

### DETAILED DESCRIPTION OF EMBODIMENTS

To enable one of ordinary skill in the art to better understand the technical solutions of the present disclosure, the present disclosure will be further described in detail below with reference to the accompanying drawings and embodiments. Obviously, described below are only some embodiments of the present disclosure, which are not intended to limit the disclosure. Based on the embodiments provided herein, all other embodiments obtained by one of ordinary skill in the art without paying creative work shall fall within the scope of the present disclosure.

An increase in the one-dimensional coupling coefficient of the photonic crystal will enhance the in-plane optical feedback of the laser and reduce the in-plane losses, where the one-dimensional coupling coefficient k_{1D} is expressed by:

$${κ}_{m , n} = - \frac{{k}_{0}^{2}}{2 {β}_{0}} {ε}_{m , n} {\int }_{PC} {\vert {Φ}_{0} ( z ) \vert}^{2} dz ;$$

where β₀ represents the wave vector, and β₀=2π/a; k₀ represents the free-space wave number, and k₀=ω/c; ω is the angular frequency; c represents the speed of light in free space; ε_{m,n} represents the Fourier coefficient of the permittivity of the photonic crystal; and Φ₀(z) represents the normalized vertical field distribution of the laser. It can be seen from the above formula, the one-dimensional coupling coefficient km varies with the Fourier coefficient ε_{m,n} of the permittivity of the photonic crystal.

For a single-lattice structure, its dielectric equation is:

$$ε ( x , y ) = {\sum }_{m , n} {F}_{m , n} {e}^{[ j ( \frac{2 π m}{a} x + \frac{2 π n}{a} y ) ]} ;$$

where F_{m,n} represents the Fourier coefficient; a represents the lattice period; m and n are non-negative integers; and x and y are spatial coordinates.

For a double-lattice structure proposed by Noda, its dielectric equation is:

$$ε ( x , y ) + ε ( x - d , y - d ) = {\sum }_{m , n} \{ 1 + {e}^{[ - j ( \frac{2 π m}{a} d + \frac{2 π n}{a} d ) ]} \} {F}_{m , n} {e}^{[ j ( \frac{2 π m}{a} x + \frac{2 π n}{a} y ) ]} ;$$

where d represents the relative offset between the air holes within the same cell.

In this equation, the effect of combining two lattices (one of which is shifted by d of the other) is represented by:

$$\{ 1 + {e}^{[ - j ( \frac{2 π m}{a} d + \frac{2 π n}{a} d ) ]} \} .$$

It can be seen that the amplitude of each Fourier expansion term for the two-lattice structure is 0-2 times the amplitude of the single-lattice structure.

For a triple-lattice structure, its dielectric constant is expressed by:

$$ε ( x , y ) + ε ( x - {d}_{1 x} , y - {d}_{1 y} ) + ε ( x - {d}_{2 x} , y - {d}_{2 y} ) = {\sum }_{m , n} \{ 1 + exp ( - j \frac{2 π m}{a} {d}_{1 x} - j \frac{2 π n}{a} {d}_{1 y} ) + exp ( - j \frac{2 π m}{a} {d}_{2 x} - j \frac{2 π n}{a} {d}_{2 y} ) \} {F}_{m , n} exp ( j \frac{2 π m}{a} x + j \frac{2 π n}{a} y ) .$$

It can be seen that the amplitude of each Fourier expansion term of the triple-lattice structure is 0-3 times the amplitude of the single-lattice structure. The triple-lattice photonic crystal structure can increase the one-dimensional coupling coefficient, thereby increasing the in-plane feedback of the laser and reducing in-plane losses.

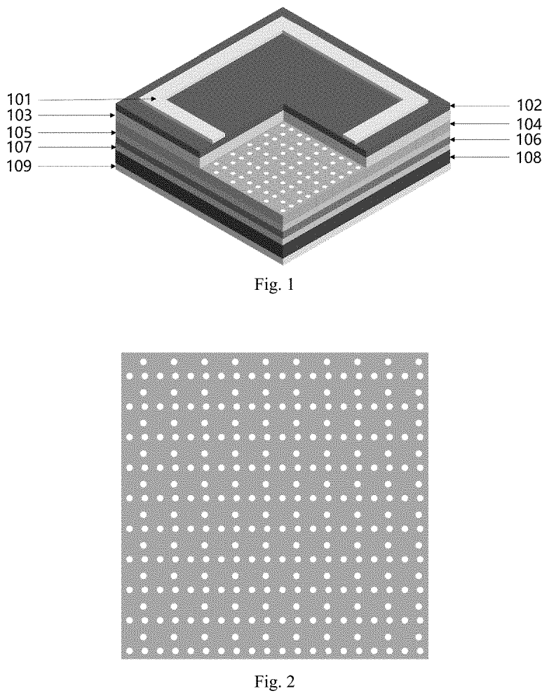

A surface-emitting semiconductor laser with a triple-lattice photonic crystal structure is provided herein, which has increased vertical radiation constants and reduced in-plane losses. FIG. 1 schematically shows the structure of the surface-emitting semiconductor laser. The surface-emitting semiconductor laser includes a P-type electrode 101, a P-type contact layer 102, a P-type cladding layer 103, a photonic crystal layer 104, an active layer 105, an N-type cladding layer 106, an N-type contact layer 107, an N-type substrate 108, and an N-type electrode 109 successively arranged from top to bottom, where the photonic crystal layer has a triple-lattice photonic crystal structure.

As shown in FIG. 2, the photonic crystal layer 104 is formed by a plurality of square unit cells arranged periodically. Each of the plurality of square unit cells has three identical air holes, namely, a first air hole, a second air hole, and a third air hole. A distance between a center of the first air hole and a center of the second air hole is (0.5±0.1) a, and a distance between a center of the third air hole and the center of the second air hole is (0.5±0.1)a, where a is a lattice constant. For example, as shown in FIG. 3, in a square unit cell, the two air holes located in the bottom are the first air hole and the second air hole, respectively. A distance between a center of the first air hole and a center of the second air hole is (0.5±0.1)a. The air hole located at the top right is the third air hole, and the center of the third air hole is located on the diagonal of the square cell and is at a distance of 0.45a from the center of the second air hole.

The surface-emitting semiconductor laser provided herein has a triple-lattice photonic crystal structure, which enhances the lateral confinement of light and reduces in-plane losses compared with existing photonic crystal structures, thereby reducing the threshold gain of the laser and improving the beam far-field profile.

In an embodiment, a cross-section of each of the first air hole, the second air hole, and the third air hole is circular, triangular, or elliptical.

In an embodiment, a longitudinal section of each of the first air hole, the second air hole, and the third air hole is drop-shaped or spindle-shaped.

In an embodiment, an air filling factor of each of the first air hole, the second air hole and the third air hole in each of the plurality of square unit cells is 4-10%.

In an embodiment, the photonic crystal layer 104 has a side length of 40-500 μm and an area of (40 μm×40 μm)−(500 μm×500 μm).

In an embodiment, the first air hole, the second air hole and the third air hole are formed on a surface of the photonic crystal layer 104 by etching; and an etching depth is 50-100% of a thickness of the P-type cladding layer.

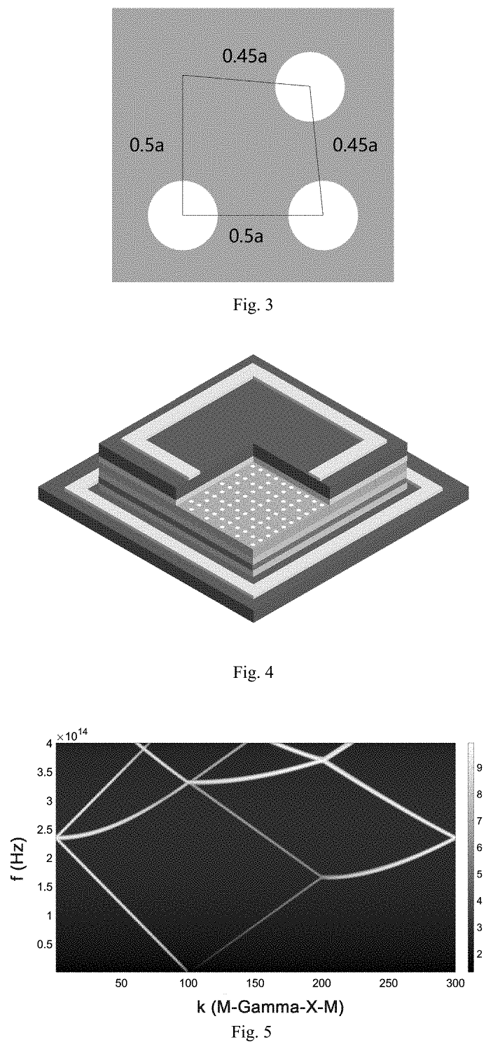

In an embodiment, the P electrode 101 and the N electrode 109 are opposed or coplanar. FIG. 4 shows a schematic diagram of a semiconductor surface-emitting laser with coplanar electrodes.

The present disclosure is described in further detail below by using the target excitation wavelength of 905 nm as a specific example.

The photonic crystal layer has a triple-lattice structure with cylindrical air holes, as shown in FIGS. 2 and 3. A distance between centers of the two bottom air holes is 0.5 a. The center of the top-right air hole in the cell of the photonic crystal is located on the diagonal of the square unit cell and is 0.45a away from the center of the bottom-right air hole. In this embodiment, the duty cycle of the three air holes is totally set to 15%. The lattice period of the photonic crystal is adjusted so that the band edge at point Γ corresponds to a frequency of 331.5 THz and a wavelength of 905 nm. Based on the band edge resonance effect of the photonic crystal, this embodiment achieves laser output in the vertical plane at 905 nm.

The material and thickness of each layer of the laser in this embodiment are as follows: the P-type contact layer is made of GaAs with a thickness of 200 nm; the P-type cladding layer is made of Al_{0.45}Ga_{0.55}As with a thickness of 1500 nm; the background material of the photonic crystal layer is made of GaAs with a hole depth of 200 nm; the active layer has an InGaAs/AlGaAs quantum well structure; the N-type cladding layer is made of Al_{0.7}Ga_{0.3}As with a thickness of 1000 nm.

FIG. 5 shows the energy band diagram of the photonic crystal of this embodiment. By adjusting the lattice constant a of the photonic crystal, the band edge at the Γ point corresponds to a frequency of 331.5 THz, and the laser can achieve excitation at 905 nm.

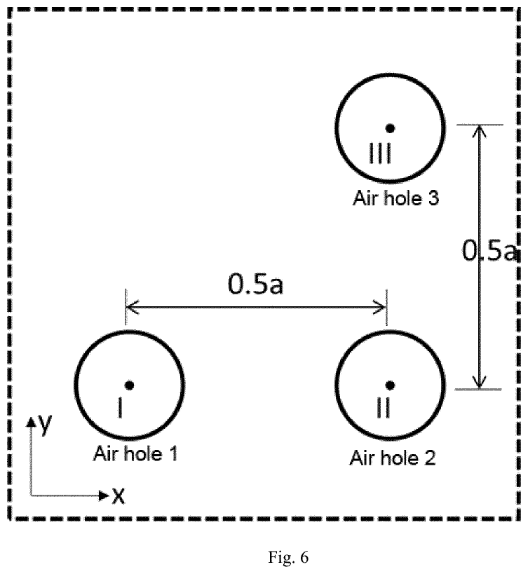

FIG. 6 shows the range of the position offset of the center of the air hole in the photonic crystal cell. The position of each air hole in the cell is shown in FIG. 6. Reference points I, II and III all have an offset component of 0.5a along x and y directions, respectively. The centroid of the air hole 1 coincides with the reference point I, while the centroid of the air hole 2 and air hole 3 coincide with or be close to reference points II and III, respectively (with an offset of no more than 0.1a along either the x or y directions), where a is the lattice constant.

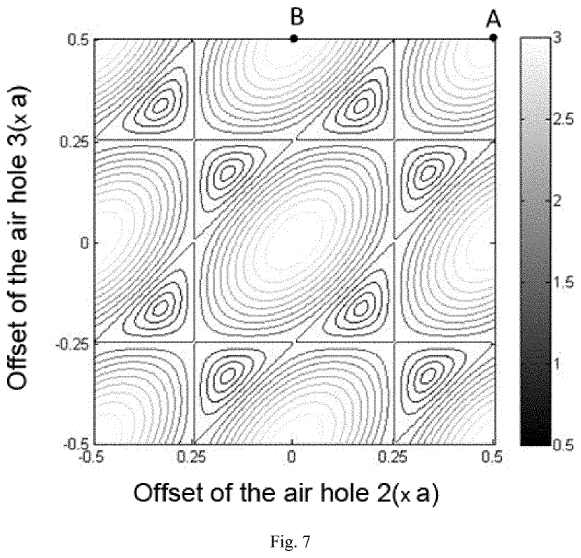

FIG. 7 shows a variation between a modulation factor amplitude and an offset of the air holes 2 and 3 of the square cell of the photonic crystal layer, and the offset refers to the offset component of the centroid of the air hole 2 and air hole 3 relative to the centroid of the air hole 1 along the x-axis, where a is the period of the square lattice. The amplitude of the modulation factor reaches a maximum value of 3 when the offset of the two air holes is (±0.5a, ±0.5a), (±0.5a, 0), and (0, ±0.5a), respectively. Whereas, the maximum value of the modulation factor for a double-lattice structure in the same case is only 2. The modulation factor along the y-direction also has the same variation relationship. In addition, to avoid the overlap between the air holes, assuming that the centroid of the air hole 1 is located at the origin, the centroid coordinates of air holes 2 and 3 are set to (0, +0.5a) and (+0.5a, +0.5a), respectively. This setting corresponds to the modulation factors along the x and y axes at points A and B in the diagram respectively. It can be observed from FIG. 7 that a deviation within a certain range can still reach such beneficial results, and the simulation results demonstrate that the surface-emitting semiconductor laser provided herein is practical and effective.

The technical features of the above-described embodiments can be arbitrarily combined. For the sake of brief description, not all possible combinations of the individual technical features of the above-described embodiments have been described herein. As long as these combinations of technical features are not contradictory, they should be considered to be within the scope of the present specification.

Described above are merely several embodiments of the present disclosure, which is specific and detailed, but should not be construed as limitations to the scope of the present disclosure. It should be noted that various variations and improvements made by one of ordinary skill in the art without departing from the spirit of the present disclosure shall fall within the scope of the present disclosure defined by the appended claims.

What is claimed is:

1. A surface-emitting semiconductor laser based on a triple-lattice photonic crystal structure, comprising:
a P-type electrode;
a P-type contact layer;
a P-type cladding layer;
a photonic crystal layer;
an active layer;
an N-type cladding layer;
an N-type contact layer;
an N-type substrate; and
an N-type electrode;
wherein the P-type electrode, the P-type contact layer, the P-type cladding layer, the photonic crystal layer, the active layer, the N-type cladding layer, the N-type contact layer, the N-type substrate, and the N-type electrode are arranged sequentially from top to bottom; and the photonic crystal layer has a triple-lattice photonic crystal structure; and
the photonic crystal layer is formed by a plurality of square unit cells arranged periodically; each of the plurality of square unit cells has a first air hole, a second air hole, and a third air hole; the first air hole, the second air hole, and the third air hole are the same; and a distance between a center of the first air hole and a center of the second air hole is (0.5±0.1) a, and a distance between a center of the third air hole and the center of the second air hole is (0.5±0.1) a, wherein a is a lattice constant.

2. The surface-emitting semiconductor laser of claim 1, wherein a cross-section of each of the first air hole, the second air hole, and the third air hole is circular, triangular, or elliptical.

3. The surface-emitting semiconductor laser of claim 1, wherein a longitudinal section of each of the first air hole, the second air hole, and the third air hole is drop-shaped or spindle-shaped.

4. The surface-emitting semiconductor laser of claim 1, wherein an air filling factor of each of the first air hole, the second air hole and the third air hole in each of the plurality of square unit cells is 4-10%.

5. The surface-emitting semiconductor laser of claim 1, wherein a side length of the photonic crystal layer is 40-500 μm.

6. The surface-emitting semiconductor laser of claim 1, wherein the P-type electrode and the N-type electrode are coplanar or opposed.

7. The surface-emitting semiconductor laser of claim 1, wherein the first air hole, the second air hole and the third air hole are formed on a surface of the photonic crystal layer by etching; and an etching depth is 50-100% of a thickness of the P-type cladding layer.
